(19) United States
(12) Patent Application Publication
(10) Pub. No.: US 2010/0025737 A1
(43) Pub. Date: Feb. 4, 2010

(54) Field-effect transistor

(75) Inventor: Kouji Ishikura, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/458,941

(22) Filed: Jul. 28, 2009

(30) Foreign Application Priority Data
Jul. 29, 2008 (JP) 2008-194712

(51) Int. Cl. H01L 29/772

(52) U.S. Cl. 257/213; 257/E29.242

(57) ABSTRACT

A field-effect transistor according to the present invention includes a source electrode that is formed in an active region, and a drain electrode that is formed in the active region. Further, the field-effect transistor includes a gate electrode that is formed in the active region and disposed between the source electrode and the drain electrode, a field plate electrode that is formed in a vicinity of the gate electrode outside a region disposed between the gate electrode and the source electrode, and an FP pad that is included in the FP electrode, the FP pad being formed outside the active region and being grounded.

### BACKGROUND

1. Field of the Invention

The present invention relates to a field-effect transistor.

2. Description of Related Art

Field-effect transistors (hereinafter referred to as “FETs”) with their high power and high linear gain characteristics are demanded for RF and microwave power amplifiers used in next generation wireless base stations. Such FETs are disclosed, for example, in Japanese Unexamined Patent Application Publication Nos. 2006-245474, 2006-286952, and 2002-94055. FETs include a GaAs-FET or a Si-MOSFET, and in recent years, an FET made of GaN or SiC. A lot of researchers have been improving the performance of the FETs by optimizing its structure. For example, a field plate (hereinafter referred to as FP) structure has been well known for the characteristics, which the FP electrode reduces an electric field at the gate edge on the drain side and suppresses current collapse, resulting in high output power at high operation voltage. The FP electrode includes a “gate FP” which is connected to a gate and a “source FP” which is connected to a source. Especially, the source FP structure also has a superior effect (Faraday shield effect). That is, the source FP electrode shields the electric flux line between the gate and the drain. The effect leads to reduce the parasitic capacitance Cgd between the gate and the drain, resulting in high linear gain.

### SUMMARY

Referring now to FIGS. 7 and 8, an FET with a source FP electrode will be described. FIG. 7 is a plane view showing the structure of the FET with a source FP electrode. FIG. 8 is a cross sectional view taken along the line VIII-VIII of FIG. 7. Hereinafter, the term “FP electrode” means a “source FP” that is connected to a source.

A gate electrode 10, a source electrode 20, and a drain electrode 30 each have finger-shaped electrodes in an active region 40 as shown in FIG. 7. That is, a gate finger 11, a source finger 21, and a drain finger 31 are formed in parallel with each other. Further, the source finger 21 is formed between two gate fingers 11. An FP electrode 50 is formed to cover the gate finger 11 so as to reduce the electric field at the gate edge. Further, the FP electrode 50 is connected to the source electrode 20. Accordingly, the FP electrode 50 is formed to cover the whole region between the gate and the source. More specifically, the FP electrode 50 is formed across the two gate fingers 11 that hold the source finger 21 therebetween. The source finger 21 is grounded through a via hole 23 in a source pad 22. Thus, the FP electrode 50 that is connected to the source electrode 20 is also grounded.

As shown in FIG. 8, the gate electrode 10 is covered with an insulting film, and the FP electrode 50 is formed on the film above the gate electrode 10. The FP electrode 50 is formed to cover the whole gate electrode 10. As described above, the FP electrode 50 is grounded through the source electrode 20. The electric flux line between the gate and the drain, therefore, is shielded by the FP electrode 50, and the parasitic capacitance Cgd between the gate and the drain is reduced. This Faraday shield effect leads to improve the linear gain and the operation stability of the device. Further, the FP electrode 50 also reduces the electric field at the gate edge on the drain side, resulting in improvement of current collapse. Thus, the FETs that have the FP electrode 50 show higher output power and higher linear gain at high operation voltage than ordinary FETs that have no FP electrodes.

In the above structure, the FP electrode 50 is formed to cover the whole gate fingers 11 in the active region 40 so as to connect sufficiently with the source electrode 20. But, this structure gives rise to the parasitic capacitance Cgs between the gate and the source, and thus reduces the linear gain.

In order to solve the aforementioned problem, an FET having a cross sectional structure shown in FIG. 9 is suggested as a second related art. FIG. 9 is a cross sectional view showing the second structure of the FET with the source FP structure. As shown in FIG. 9, an air space 80 is arranged below the FP electrode 50. Note that a low dielectric-constant film may be provided instead of the air space 80. As such, the parasitic capacitance Cgs is reduced. In order to make the structure, multiple and complicated process is required, and it is extremely difficult to fabricate the device in practice.

An FET having a plane pattern as shown in FIG. 10 is suggested as a third related art. FIG. 10 is a plane view showing the third structure of the FET having the source FP structure. As shown in FIG. 10, an FP finger 51 is formed in a vicinity of each of the gate fingers 11. Now, the FP finger 51 is a part of the FP electrode 50 and has a finger shape in the active region 40. Then, each FP finger 51 is connected to the source finger 21 through FP bridges 81. Now, the FP bridge 81 is a part of the FP electrode 50, and it connects the source finger 21 and the FP finger 51 over the gate finger 11. FIG. 10 illustrates the FP electrode 50 having a plane pattern which is partially opened between the gate finger 11 and the source finger 21. Thus, the parasitic capacitance Cgs is reduced. The FP bridges 81, however, are definitely needed to connect them and the linear gain reduction by the parasitic capacitance Cgs caused by the bridges 81 cannot be ignored.

Further, an FET having a plane pattern as shown in FIG. 11 is suggested as a fourth related art. FIG. 11 is a plane view showing the fourth structure of the FET with the source FP structure. As shown in FIG. 11, the FP bridges 81 are formed only at the bottom and the top of the finger. That is, the FP electrode 50 is connected to the source electrode 20 only at the bottom and the top of the finger. The parasitic capacitance Cgs, however, still remains in this fourth related art, even though it is reduced compared with the third related art. Further, as a part in which the FP electrode 50 and the source electrode 20 are connected is made smaller, the grounding characteristics are degraded.

A first exemplary aspect of an embodiment of the present invention is a field-effect transistor including a source electrode that is formed in an active region, a drain electrode that is formed in the active region, a gate electrode that is formed in the active region and disposed between the source electrode and the drain electrode, a field plate electrode that is formed in a vicinity of the gate electrode outside a region disposed between the gate electrode and the source electrode, and an FP pad that is included in the field plate electrode, the FP pad being formed outside the active region and being grounded. According to the present invention, it is possible to provide a field-effect transistor that realizes the effect of FP (field plate) and has high RF linear gain without complicated fabrication process.

According to the present invention, it is possible to provide a field-effect transistor with high output power and high linear gain fabricated without complicated process.

### BRIEF DESCRIPTION OF THE DRAWINGS

The above and other objects, advantages and features of the present invention will be more apparent from the following description of certain exemplary embodiments taken in conjunction with the accompanying drawings, in which:

FIG. 1 is a plane view showing the structure of an FET according to an exemplary embodiment;

FIG. 2 is a cross sectional view taken along the line II-II of FIG. 1;

FIG. 3 is a plane view showing another structure of the FET according to the exemplary embodiment;

FIG. 4 is a graph showing a result of comparing RF power performance of the FET according to the present invention with a related FET;

FIG. 5 is a graph showing a relation between an FP aperture ratio and a linear gain;

FIG. 6 is a graph showing a simulation result of a relation between an FP aperture ratio and a grounding characteristics;

FIG. 7 is a plane view showing the structure of an FET with a source FP structure according to a related art;

FIG. 8 is a cross sectional view taken along the line VIII-VIII of FIG. 7;

FIG. 9 is a cross sectional view showing a second structure of an FET with a source FP structure according to a related art;

FIG. 10 is a cross sectional view showing the third structure of the FET with the source FP structure according to the related art; and

FIG. 11 is a cross sectional view showing the fourth structure of the FET with the source FP structure according to the related art.

### DETAILED DESCRIPTION OF THE EXEMPLARY EMBODIMENTS

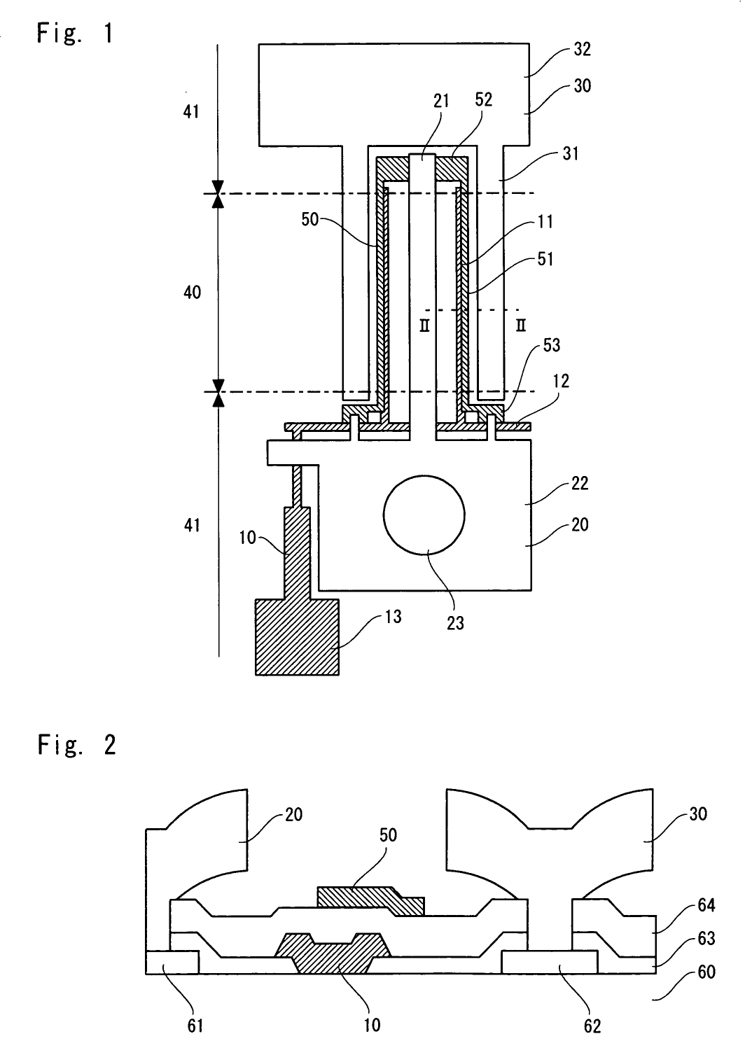

Referring first to FIGS. 1 and 2, a field-effect transistor (hereinafter referred to as FET) according to the present invention will be described. FIG. 1 is a plane view showing the structure of the FET. FIG. 2 is a cross sectional view taken along the line II-II of FIG. 1. The FET has the structure in which a lot of units are arrayed on a semiconductor substrate 60, and a unit is composed of source, gate and drain. In FIG. 1, two adjacent units are shown. The FET can be used as a microwave amplifier or a switching device for power electric appliance.

In the semiconductor substrate 60, an active region 40 and a non-active region 41 disposed outside the active region 40 are formed. In the active region 40, a channel region, a source region, and a drain region are disposed. In short, the active region 40 means an operation region that can be operated as an FET. The FET includes a gate electrode 10, a source electrode 20, and a drain electrode 30. Each of these electrodes includes a plurality of fingers. More specifically, these electrodes in a plurality of units are arrayed like a comb-tooth pattern. In the active region 40, a plurality of gate fingers 11, a plurality of source fingers 21, and a plurality of drain fingers 31 are formed in parallel with each other. These fingers are formed on the active region 40. Both ends of these fingers are formed to protrude into the non-active region 41. The drain finger 31, the gate finger 11, the source finger 21, the gate finger 11, and the drain finger 31 are arranged in this order in the active region 40. That is, the gate finger 11 is disposed between the source finger 21 and the gate finger 31 in one unit.

The source finger 21 is formed on a source region of the active region 40. The source finger 21 extends from a source pad 22 that is formed in the non-active region 41. That is, the bottom end of the source finger 21 is connected to the source pad 22. Further, the source finger 21 protrudes into the non-active region 41 near a drain pad 30, and the top end of the source finger 21 is positioned on a top side FP pad 52 described later.

Then, in the non-active region 41, the top end of the source finger 21 is contacted to the top side FP pad 52. The source pad 22 is grounded through a via hole 23. Further, the source pad 22 is formed in substantially a rectangular shape, and a part of source pad 22 protrudes toward the active region 40 side. The protruding part of the source pad 22 is connected to a bottom side FP pad 53 described later.

The drain finger 31 is formed on a drain region of the active region 40. The drain finger 31 extends from the drain pad 32 that is formed in the non-active region 41. That is, bottom end of the drain finger 31 is connected to the drain pad 32. Further, the top end of the drain finger 31 is positioned between the bottom side FP pad 53 and the active region 40. That is, the drain finger 31 is not formed on the bottom side FP pad 53. The drain pad 32 is connected to the end part of the drain finger 31 that is in the opposite side of the source pad 22. The active region 40 is disposed between the drain pad 32 and the source pad 22.

The gate finger 11 is formed on a channel region of the active region 40. The gate finger 11 extends from a gate bus bar 12 formed in the non-active region 41. That is, the bottom end of the gate finger 11 is connected to the gate bus bar 12. Further, the top end of the gate finger 11 is positioned between the top side FP pad 52 and the active region 40. That is, the gate finger 11 is not formed to be overlapped with the top side FP pad 52. The gate bus bar 12 is formed to be perpendicular to the gate finger 11. Further, the gate bus bar 12 is disposed between the source pad 22 and the bottom side FP pad 53. The gate bus bar 12 is electrically connected to a gate pad 13 that is formed in the non-active region 41.

In the FET according to the exemplary embodiment, a field plate (hereinafter referred to as FP) electrode 50 is formed. The term “FP electrode” here means a “source FP” that is connected to a source electrode. A part of the FP electrode 50 is formed in a vicinity of the gate finger 11. The FP finger 51 is disposed above the gate finger 11 and between the gate finger 11 and the drain finger 31. The FP finger 51 extends so as to be made parallel with the gate finger 11, the source finger 21, and the drain finger 31. The FP finger 51 is formed outside the region that is disposed between the gate finger 11 and the source finger 21. That is, the FP finger 51 is not formed between the adjacent gate finger 11 and the source finger 21.

Further, the FP finger 51 extends from the top side FP pad 52 and the bottom side FP pad 53. Now, the FP pad means a connecting point with a source electrode in the FP electrode 50. That is, the top side FP pad 52 or the bottom side FP pad 53 is formed in both ends of the FP finger 51. The top side FP pad 52 and the bottom side FP pad 53 are formed in the non-active region 41. The top side FP pad 52 is formed in the top side of the source finger 21. The top side FP pad 52 is formed between the drain pad 32 and the gate finger 11. Further, the top side FP pad 52 is formed between the two drain fingers 31. As described above, the top side FP pad 52 is connected to the source finger 21. That is, the FP electrode 50 is grounded through the source electrode 20 by the top side FP pad 52.

The bottom side FP pad 53 is formed in the bottom side of the gate finger 11. The bottom side FP pad 53 is formed between the gate bus bar 12 and the drain finger 31. The bottom side FP pad 53 is formed in accordance with each FP finger 51. As described above, the bottom side FP pad 53 is connected to the protruding part of the source pad 22. That is, the FP electrode 50 is grounded through the bottom side FP pad 53 connected to the source electrode 20. As such, the FP pads 52 and 53 are arranged in the top side of the source finger 21 and the bottom of the gate finger 11, respectively, in the non-active region 41. Then, the FP electrode 50 is connected to the source through the top side FP pad 52 and the bottom side FP pads 53, respectively.

As shown in FIG. 2, a source ohmic metal 61 and a drain ohmic metal 62 are formed on the semiconductor substrate 60 such as a GaAs substrate or the like. The source ohmic metal 61 is formed on the source region of the active region 40. The drain ohmic metal 62 is formed on the drain region of the active region 40. The source ohmic metal 61 and the drain ohmic metal 62 are ohmic-contacted with the active region 40 of the semiconductor substrate 60. A first insulating film 63 is formed on the source ohmic metal 61 and the drain ohmic metal 62. A gate electrode 10 is formed on the first insulating film 63. A gate aperture is formed in the first insulating film 63 on the channel region of the active region 40. The gate electrode 10 is embedded in this aperture, and the gate electrode 10 and the channel region are connected. The gate electrode 10 is formed substantially in a T shape.

On the first insulating film 63, a second insulating film 64 is formed to cover the gate electrode 10. On the second insulating film 64, the source electrode 20, the drain electrode 30, and the FP electrode 50 are formed. A source aperture is formed in the first insulating film 63 and the second insulating film 64 above the source ohmic metal 61. The source electrode 20 is embedded in this aperture, and the source electrode 20 is connected to the source ohmic metal 61. A drain aperture is formed in the first insulating film 63 and the second insulating film 64 above the drain ohmic metal 62. The drain electrode 30 is embedded in this aperture, and the drain electrode 30 is connected to the drain ohmic metal 62. Further, in the source electrode 20 and the drain electrode 30 are formed apart from positions on the second insulating film 64. That is, there are spaces between these electrodes and the second insulating film 64.

The FP electrode 50 is formed in the vicinity of a position above the gate electrode 10 with the second insulating film 64 interposed therebetween. More specifically, the FP electrode 50 is formed closer to the gate electrode 10 than the drain electrode 30. The FP electrode 50 is formed above a part of the gate electrode 10 toward the drain side. Thus, the Faraday shield effect can be obtained. Further, the area where the FP electrode 50 is formed, the shape of the FP electrode 50 and the like are not specifically limited as long as the effect of FP can be obtained. The FP electrode 50 may be formed, for example, only between the gate electrode 10 and the drain electrode 30 or only above the gate electrode 10 so long as the effect of FP can be obtained. Further, the FP electrode 50 is formed so as not to protrude toward the source side.

As shown in the description above, in the FET according to the exemplary embodiment, there is no part in the active region 40 where a region between the gate and the source is covered with the FP electrode 50. Thus, a parasitic capacitance Cgs between the gate and the source can be reduced. Thus, the RF linear gain can be improved. Further, as the FP electrode 50 that is connected to the source electrode 20 is formed in the non-active region 41, the effect of FP can also be obtained. That is, a parasitic capacitance Cgd between the gate and the drain can be reduced by the Faraday shield effect. Further, as it is possible to reduce the peak of the electric field at the gate edge on the drain side and disperse it toward the FP electrode edge, the current collapse can be improved, which means power performance at high operation voltage can be improved. As such, it is possible to improve the RF linear gain while maintaining the effect of FP.

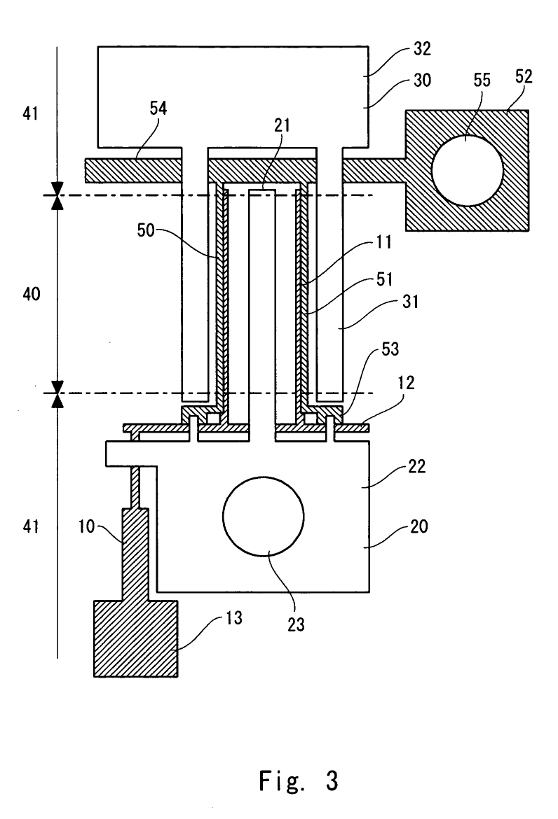

Note that either one of the FP pads (the top side FP pad 52 or the bottom side FP pad 53) may be used to contact to the source electrode 20 according to the unit finger width or the frequency. Further, if the FP electrode 50 can be grounded, the FP pads 52 and 53 may not be contacted with the source electrode 20. For example, as shown in FIG. 3, the top side FP pad 52 may be directly grounded. Referring now to FIG. 3, another structure of the FET will be described. FIG. 3 is a plane view showing another structure of the FET.

As shown in FIG. 3, the plurality of FP fingers 51 extend from an FP bar 54 formed in the non-active region 41. The FP bar 54 is formed between the source finger 21 and the drain pad 32. Further, the FP bar 54 is formed between the gate finger 11 and the drain pad 32. That is, the FP bar 54 is not formed to overlap with the gate finger 11 and the source finger 21. The FP bar 54 extends in a direction perpendicular to a direction in which the FP fingers 51 extend.

The FP bar 54 is electrically connected to the top side FP pad 52 formed in the non-active region 41. The top side FP pad 52 is grounded through a via hole 55. More specifically, the FP electrode 50 is directly grounded through the via hole 55 instead of connecting the source finger 21 and the FP electrode 50 for grounding. The same effect as above can be obtained with such a structure. Further, the top side FP pad 52 may be grounded by bonding, not only by the via hole 55. As such, the method of grounding is not limited as long as it allows the grounding of the FP electrode 50, and the pattern of the FP pads 52 and 53 may be a long bar shape as above.

Next, a method of manufacturing the FET shown in FIGS. 1 and 2 will be described. Note that the method of manufacturing the FET will be simply described as the method similar to the related one may be employed. First, the active region 40 and the non-active region 41 are formed in the semiconductor substrate 60. Then, the source ohmic metal 61 and the drain ohmic metal 62 are formed in a desired shape on the semiconductor substrate 60. Next, the first insulating film 63 is formed so as to cover the source ohmic metal 61 and the drain ohmic metal 62, and the gate aperture is formed in the first insulating film 63. Then, the gate electrode 10 having a T shape is formed to be embedded in the aperture of the first insulating film 63. Then, the second insulating film 64 is formed to cover the gate electrode 10.

Next, the FP electrode 50 is formed on the second insulating film 64. Note that the material of the FP electrode 50 may be Au, Pt, Ti, TiN or the like, but it is not limited to them. Further, the method of forming the FP electrode 50 includes deposition lift-off, sputtering or the like, but it is not limited to them. The FP electrode 50 is formed, as shown in FIG. 1, also in the non-active region 41. More specifically, the top side FP pad 52 is formed in the top side of the source finger 21 which will be formed later. Then, the bottom side FP pad 53 is formed in the bottom side of the gate finger 11, i.e. between the gate bus bar 12 and the drain finger 31.

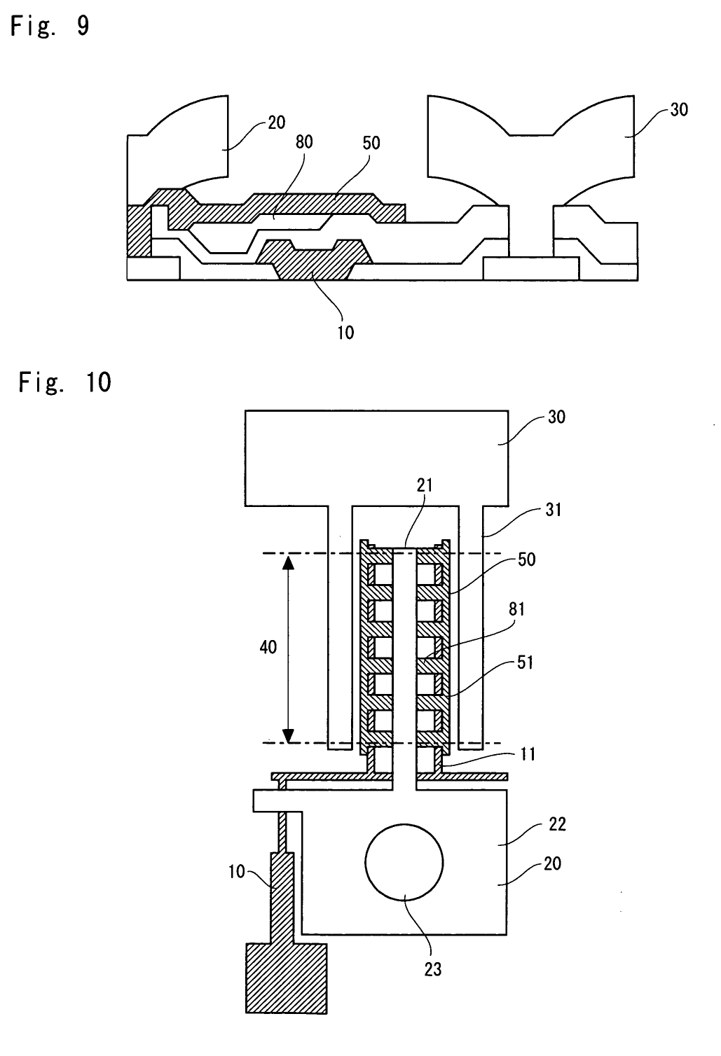

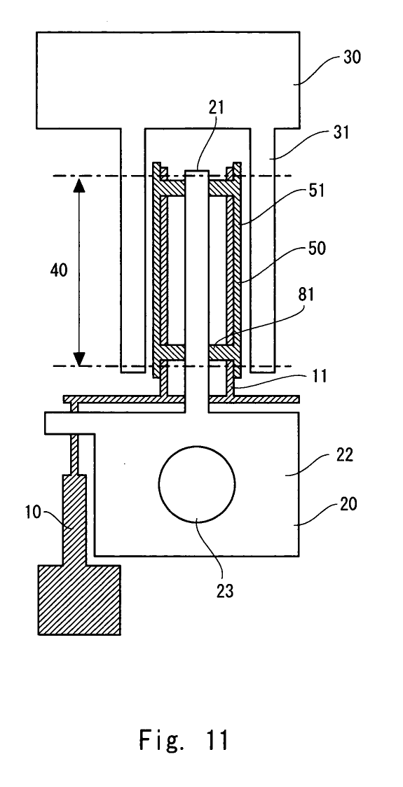

Source and drain apertures are formed in the first insulating film 63 and the second insulating film 64 above each of the source ohmic metal 61 and the drain ohmic metal 62. Then, the source electrode 20 and the drain electrode 30 are formed to be embedded in the apertures on the source ohmic metal 61 and the drain ohmic metal 62. As such, the source ohmic metal 61 is connected to the source electrode 20, and the drain ohmic metal 62 is connected to the drain electrode 30. At this time, the source electrode 20 is connected to the FP electrode 50 by extending the source electrode 20 toward the FP pads 52 and 53. As for the back side process, the via hole 23 is formed from the back side to be aligned with the source pad 22. Next, a back side metal is formed to be embedded in the via hole 23. The back side metal may be formed of Ti, Pt, Au or the like, but it is not limited to them. As the back side metal and the source pad 22 are connected through the via hole 23, the source electrode 20 and the FP pads 52 and 53 are grounded as well. The FET according to the exemplary embodiment is formed as above. Further, the FET having excellent characteristics can be obtained without an additional complicated process as the FET shown in FIG. 9. Thus, it is possible to make the manufacturing process simple, and to improve productivity.

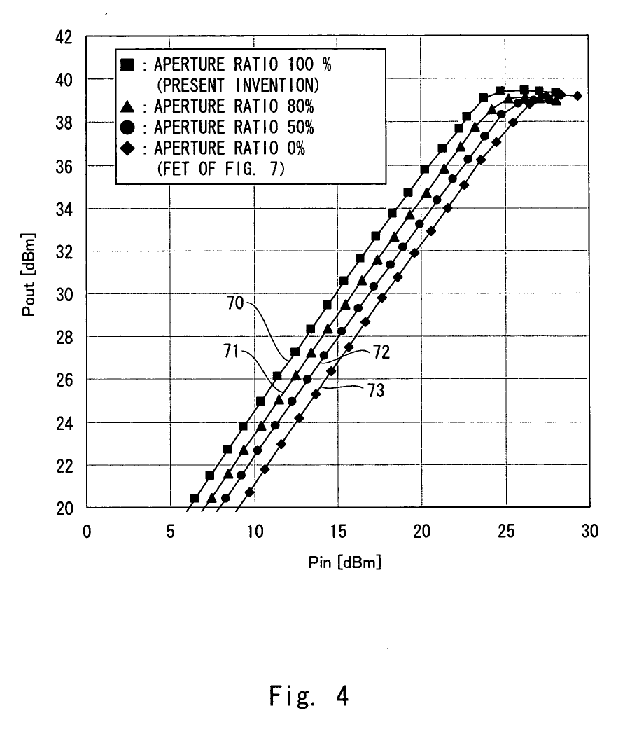

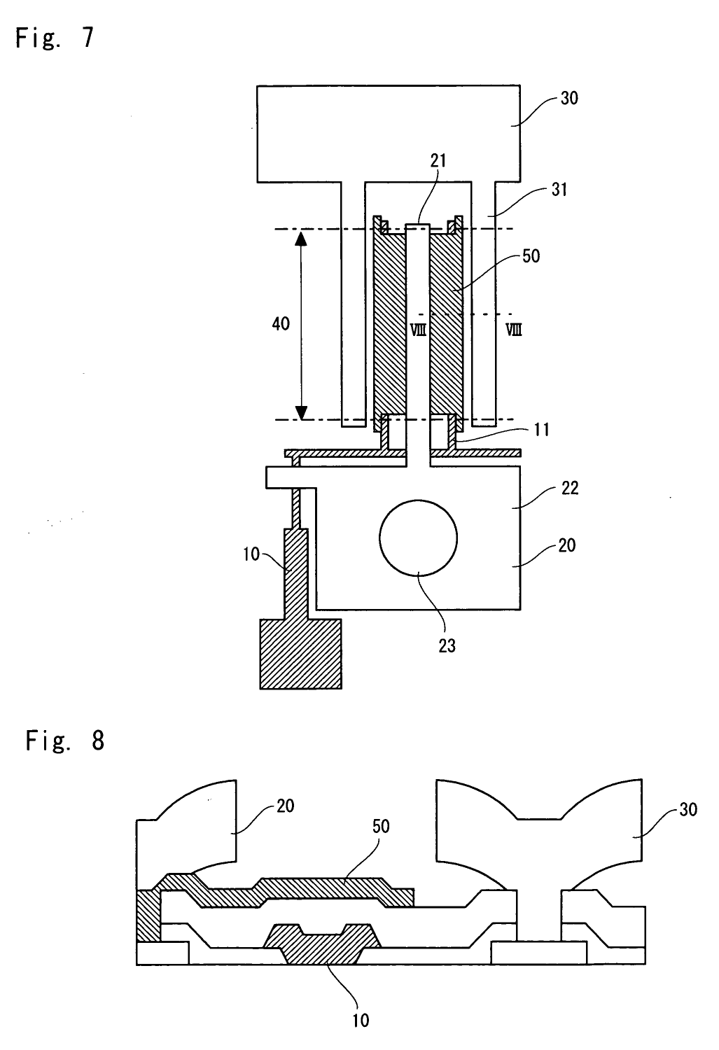

FIG. 4 shows a result of comparing the RF power performance of the FET according to the present invention with a related FET shown in FIGS. 7 and 10. In FIG. 4, it is supposed that the unit finger width is 1000 μm, the gate width is 10 mm, and the frequency is 2 GHz. In FIG. 4, a horizontal axis shows an input power Pin [dBm] and a vertical axis shows an output power Pout [dBm]. The performance of the symbol 70 is for the FET with an FP aperture ratio of 100%, the performance of the symbol 71 is for the FET with an FP aperture ratio of 80%, the performance of the symbol 72 is for the FET with an FP aperture ratio of 50%, and the performance of the symbol 73 is for the FET with an FP aperture ratio of 0%.

The FP aperture ratio here means the ratio of the open area which is not covered with the FP electrode 50 in the area between the gate and the source in the active region 40. More specifically. The FET with the FP aperture ratio of 100% is the one for the present invention, the FET with the FP aperture ratio of 0% is shown in FIG. 7 and the FET with the FP aperture ratio of 80% or the FP aperture ratio of 50% has the FP pattern as shown in FIG. 10. As shown in FIG. 4, at the same input power Pin, the output power Pout becomes higher as the FP aperture ratio becomes higher.

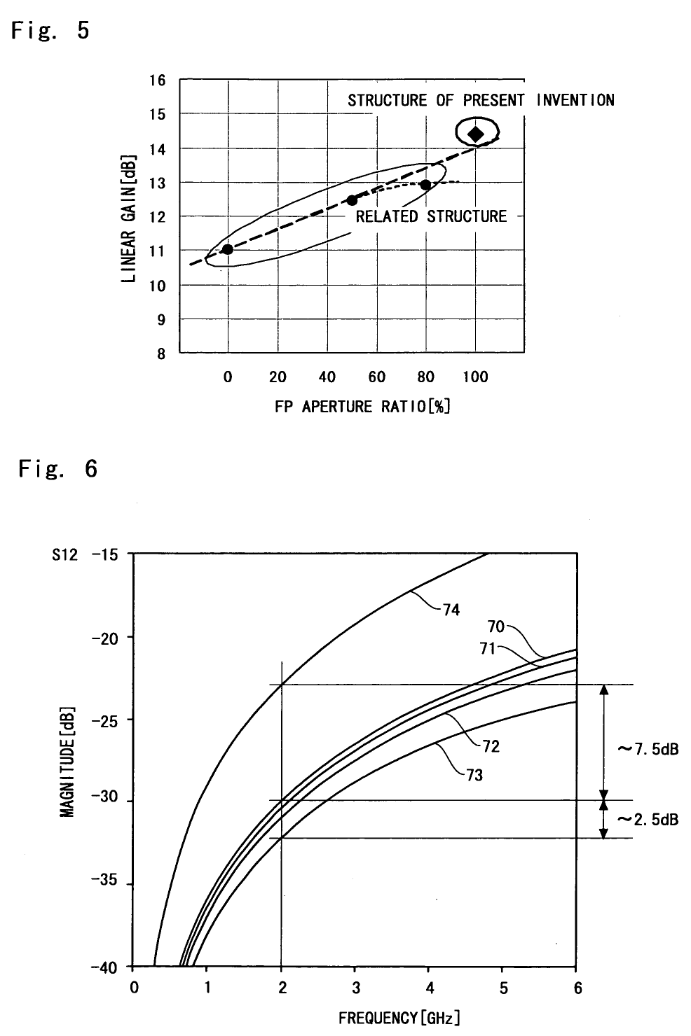

FIG. 5 shows the relation between the FP aperture ratio and the linear gain. In FIG. 5, a horizontal axis shows an FP aperture ratio [%] , and a vertical axis shows a linear gain [dB] . As shown in FIG. 5, the linear gain increases as the FP aperture ratio increases. More specifically, as the open area of the FP electrode 50 between the gate and the source becomes wider, the linear gain increases. This is because the parasitic capacitance Cgs is reduced as the area in which the FP electrode 50 covers between the gate and the source decreases. According to the present invention in which the FP aperture ratio is 100%, the linear gain is improved by 3 dB or more compared with that of the FET with the FP aperture ratio of 0%.

According to the related structure, because the source electrode 20 is connected to the FP electrode 50 in the active region 40, it is impossible to realize the FP aperture ratio of 100%. Further, if the FP aperture ratio of the related structure is made close to 100%, the grounding characteristics of the FP electrode 50 are degraded, and the linear gain may be decreased. Thus, also in FIG. 5, the gain slightly decreases when the FP aperture ratio of the related structure is 80%. When compared with the related structure having the same FP aperture ratio, the linear gain in the present invention may further be improved, because the grounding characteristics in the present invention are improved due to the FP pads 52 and 53 in the non-active region 41.

FIG. 6 shows a simulation result of a relation between the FP aperture ratio and the grounding characteristics of the FP electrode 50. In FIG. 6, a horizontal axis shows a frequency [GHz], and a vertical axis shows an S12 [dB]. Now, the S12 is one of the S parameters of the FET, and indicates the magnitude of a signal that comes back from the output port to the input port of the FET. In short, smaller S12 indicates fewer signals coming back to the input port, and indicates good isolation characteristics. In this exemplary embodiment, the source finger 21, the gate finger 11, the drain finger 31, and the FP finger 51 having unit finger widths of 1000 μm are arranged in parallel one by one to calculate the S12 between the gate and the drain.

As shown in FIG. 6, the isolation S12 becomes smaller as the FP aperture ratio decreases. In other words, as the FP aperture ratio decreases, the grounding characteristics of the FP electrode 50 are improved, an electric flux line between the gate and the drain is shielded, and the isolation S12 is improved. That is, the isolation S12 is improved by the Faraday shield effect. Now, the grounding characteristics are compared between the FET having the FP electrode 50 and the FET which does not have the FP electrode 50 shown by the symbol 74. First, in the frequency of 2 GHz, the FET having the FP aperture ratio of 0% where the whole region between the gate and the source is covered with the FP electrode 50 and the FET which does not have the FP electrode 50 are compared. FIG. 6 shows that the isolation S12 of the FET having the FP aperture ratio of 0% is improved by 10 dB compared with that of the FET without the FP electrode. Further, in the frequency of 2 GHz, the FET having the FP aperture ratio of 100% which is grounded in the both ends of the FP electrode 50 and the FET which does not have the FP electrode 50 are compared. FIG. 6 shows that the isolation S12 of the FET having the FP aperture ratio of 100% is improved by 7.5 dB compared with that of the FET without FP electrode.

Next, the grounding characteristics of the FETs by the difference of the FP aperture ratio will be compared. Comparing the FET having the FP aperture ratio of 100% with the FET having the FP aperture ratio of 0% in the frequency of 2 GHz, it can be seen that there is only a difference of about 2.5 dB in the isolation S12. Then, it is estimated that the gain (MSG: Maximum Stable Gain) is degraded by 1.25 dB. It is therefore seen that the difference of the isolation S12 by the FP aperture ratio is not that large compared with the difference of the isolation S12 between the FETs with/without the FP electrode. It is seen that the difference of the grounding characteristics by the FP aperture ratio does not affect the linear gain that much.

Accordingly, considering the result of FIG. 5, the parasitic capacitance Cgs between the gate and the source is more important factor for the linear gain of the FET with the FP electrode 50 than its grounding characteristics, although the grounding characteristics surely are important as well. That is, if the grounding characteristics can be maintained to some extent by the FP pads 52 and 53 in the non-active region 41, the gain can be further improved when the parasitic capacitance Cgs in the active region 40 is reduced rather than widely connecting the FP electrode 50 and the source electrode 20 in the active region 40 to maintain the grounding characteristics.

However, according to the calculation result of FIG. 6, the grounding characteristics gradually degrade as the frequency becomes higher. Accordingly, when used at high frequency while keeping the unit finger width of 1000 μm, it is expected that the whole long FP electrode 50 cannot be grounded only by the FP pads 52 and 53, and the linear gain may be decreased by the degradation of the grounding characteristics. In general, however, the shorter unit finger width is used for a high frequency FET to suppress the phase shift, so the grounding characteristics are improved as well. In a practical use, therefore, grounding the FP electrode 50 at the top side FP pad 52 and the bottom side FP pad 53 will be suitable for any frequency FETs. On the other hand, for a low frequency FET, the difference of the grounding characteristics by the FP aperture ratio becomes small, so either one of the FP pads (the top side FP pad 52 or the bottom side FP pad 53) may be fine.

As the FP pads 52 and 53 are arranged in the non-active region 41 isolated from the active region 40 and have the same potential (ground) as the back side, the effect of the FP does not depend on a shape of an FP pad, and there is no difference of the frequency dependence according to its shape. Although the FP pads 52 and 53 may have any shape, the large area connected the FP pads 52 and 53 to the source is obviously better to improve the grounding characteristics if there is no restriction of the process (alignment margin or the like).

From the aforementioned result, when the FP electrode 50 is added to the FET, high breakdown voltage and high linear gain can be obtained by the electric field reduction effect or the Faraday shield effect. The linear gain, however, is degraded or the RF performance may be unstable depending on the patterns or structures to connect the FP electrode 50. This is because the parasitic capacitance Cgs is produced in a region between the gate and the source covered with the FP electrode 50, when the FP electrode 50 is connected to the source electrode 20. In the FET according to the present invention, the FP pads 52 and 53 are provided in the non-active region 41 to ground the FP electrode 50 in order to effectively solve the problem without an additional process. As such, it is possible to eliminate the region between the gate and the source covered with the FP electrode 50 in the active region 40. Thus, the RF linear gain can be improved while maintaining the effect of FP.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A field-effect transistor, comprising:
a source electrode that is formed in an active region;
a drain electrode that is formed in the active region;
a gate electrode that is formed in the active region and disposed between the source electrode and the drain electrode;
a field plate electrode that is formed in a vicinity of the gate electrode outside a region disposed between the gate electrode and the source electrode; and
an FP pad that is included in the field plate electrode, the FP pad being formed outside the active region and being grounded.

2. The field-effect transistor according to claim 1, wherein
the source electrode is grounded, and
the FP pad is contacted with the source electrode.

3. The field-effect transistor according to claim 1, wherein the FP pad is grounded by a via hole or by bonding.

4. The field-effect transistor according to claim 2, wherein the FP pad is grounded by a via hole or by bonding.

5. The field-effect transistor according to claim 1, wherein
the FP electrode comprises an FP finger, and
the FP pad is formed in each of both ends of the FP finger.

6. The field-effect transistor according to claim 2, wherein
the FP electrode comprises an FP finger, and
the FP pad is formed in each of both ends of the FP finger.

7. The field-effect transistor according to claim 3, wherein
the FP electrode comprises an FP finger, and
the FP pad is formed in each of both ends of the FP finger.

8. The field-effect transistor according to claim 4, wherein
the FP electrode comprises an FP finger, and
the FP pad is formed in each of both ends of the FP finger.
